(19) United States
(12) Patent Application Publication
(10) Pub. No.: US 2025/0107189 A1
(43) Pub. Date: Mar. 27, 2025

(54) SEMICONDUCTOR DEVICE AND MANUFACTURING METHOD THEREOF

(71) Applicant: Hon Young Semiconductor Corporation, Hsinchu City (TW)

(72) Inventor: Jian-Yi WU, Hsinchu City (TW)

(21) Appl. No.: 18/442,114

(22) Filed: Feb. 15, 2024

(30) Foreign Application Priority Data
Sep. 27, 2023 (TW) 112137127

(51) Int. Cl. H01L 29/04; H01L 21/02; H01L 21/04; H01L 21/3065; H01L 21/308; H01L 21/467; H01L 29/16; H01L 29/20; H01L 29/24; H01L 29/66; H01L 29/78

(52) U.S. Cl. CPC H10D 62/405; H01L 21/0243; H01L 21/02433; H01L 21/02658; H01L 21/042; H01L 21/0475; H01L 21/3083; H01L 21/467; H10D 12/031; H10D 30/01; H10D 30/021; H10D 30/60; H10D 62/8303; H10D 62/8325; H10D 99/00; H01L 21/02376; H01L 21/02378; H01L 21/02389; H01L 21/02414; H01L 21/3065; H10D 62/80; H10D 62/8503

(57) ABSTRACT

The semiconductor device includes a substrate, an epitaxial layer and a transistor structure. The substrate is a hexagonal crystal structure and has a top surface perpendicular to a c-axis. The top surface of the substrate includes a lattice plane that is parallel to the c-axis, in which the lattice plane is etched by using a developed photoresist, and an included angle between the top surface of the developed photoresist and the substrate is in a range from 30 degree to 60 degree. The epitaxial axis is located on the lattice plane. The transistor structure is located in the epitaxial layer, on the epitaxial layer and on a surface facing away from the epitaxial layer.

### RELATED APPLICATIONS

This application claims priority to Taiwan Application Serial Number 112137127, filed, Sep. 27, 2023, which is herein incorporated by reference.

### BACKGROUND

### Field of Disclosure

The present disclosure relates to a semiconductor device and a manufacturing method of a semiconductor device.

### Description of Related Art

When manufacturing a silicon carbide power device, electron mobility is one of the key factors. Electron mobility affects the on-state resistance, and thus the on-state resistance determines the power consumption of the power device. Therefore, a method to manufacture a silicon carbide power device with high electron mobility is an important topic for the designers of the silicon carbide devices.

Silicon carbide (SiC) has a hexagonal crystal structure, and is strongly anisotropic on the electron mobility. For example, for 4H—SiC, the electron mobility on the direction parallel to the c-axis is 20 percent higher than the electron mobility on the direction perpendicular to the c-axis. Therefore, designing a transistor structure with high the electron mobility is an important topic.

### SUMMARY

One aspect of the present disclosure provides a semiconductor device.

According to one embodiment of the present disclosure, a semiconductor device includes a substrate, an epitaxial layer and a transistor structure. The substrate is a hexagonal crystal structure and has a top surface perpendicular to a c-axis. The top surface of the substrate includes a lattice plane that is parallel to the c-axis, in which the lattice plane is etched by using a developed photoresist, and an included angle between the top surface of the developed photoresist and the substrate is in a range from 30 degree to 60 degree. The epitaxial axis is located on the lattice plane. The transistor structure is located in the epitaxial layer, on the epitaxial layer and on a surface facing away from the epitaxial layer.

One aspect of the present disclosure provides a semiconductor device.

According to one embodiment of the present disclosure, a semiconductor device includes a substrate, an epitaxial layer and a transistor structure. The substrate is a hexagonal crystal structure and has a top surface perpendicular to a c-axis. The top surface of the substrate includes a lattice plane that is parallel to the c-axis, in which the lattice plane is etched by using a developed photoresist, and an included angle between the top surface of the developed photoresist and the substrate is in a range from 30 degree to 60 degree. The epitaxial axis is located on the lattice plane and directly contacts the lattice plane. The transistor structure is located in the epitaxial layer and on the epitaxial layer.

One aspect of the present disclosure provides a manufacturing method of a semiconductor device.

According to one embodiment of the present disclosure, a manufacturing method of a semiconductor device includes coating a photoresist on a top surface of a substrate, in which the substrate is a hexagonal crystal structure and has a top surface perpendicular to a c-axis; developing the photoresist such that an included angle is between a top surface of the photoresist and the substrate, in which the included angle is in a range from 30 degree to 60 degree; etching the substrate with the photoresist such that a lattice plane of the substrate parallel to the c-axis is exposed; growing an epitaxial layer on the substrate such that the epitaxial layer is grown along the lattice plane parallel to the c-axis; and forming a transistor structure in the epitaxial layer, on the epitaxial layer and on a surface facing away from the epitaxial layer.

In the aforementioned embodiments of the present disclosure, since a (11-20) lattice plane or a (1-100) lattice plane is etched through the development of the photoresist and the dry etching, the epitaxial layer will be grown along the (11-20) lattice plane or the (1-100) lattice plane parallel to the c-axis in the epitaxial growth thereafter, and thus obtain an epitaxial layer along the (11-20) lattice plane or the (1-100) lattice plane parallel to the c-axis. In the formation of the transistor structure thereafter, a transistor structure that is parallel to the c-axis and has higher electron mobility can be obtained.

### BRIEF DESCRIPTION OF THE DRAWINGS

FIG. 1 is a flow chart of a manufacturing method of a semiconductor device according to one embodiment of the present disclosure.

FIG. 2 is a perspective view of a unit cell of a hexagonal crystal structure.

FIG. 3 to FIG. 7 are cross-sectional views of intermediate steps of the manufacturing method of the semiconductor device according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the drawings. The spatially relative terms are intended to encompass different orientations of the device in use or operation in addition to the orientation depicted in the drawings. The apparatus may be otherwise oriented (rotated 90 degrees or at other orientations) and the spatially relative descriptors used herein may likewise be interpreted accordingly.

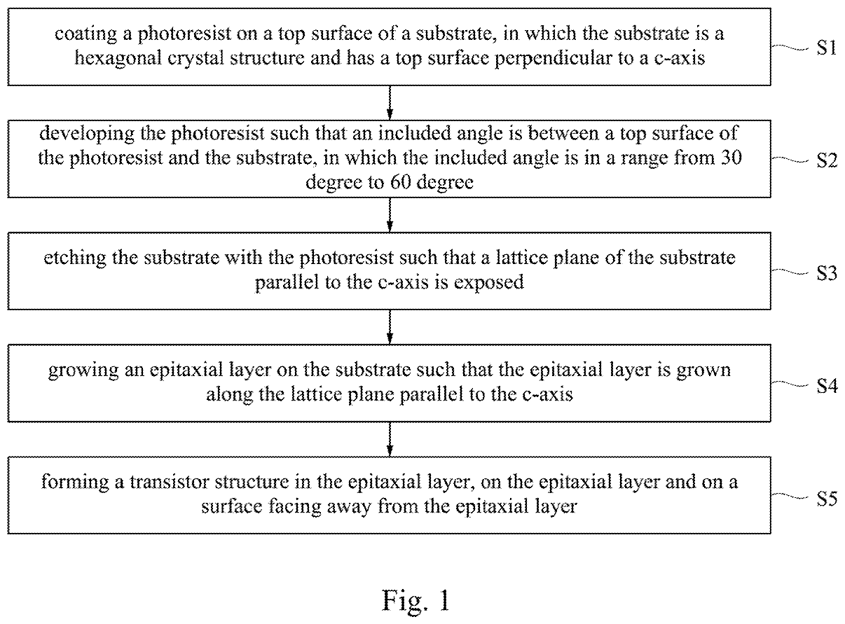

FIG. 1 is a flow chart of a manufacturing method of a semiconductor device according to one embodiment of the present disclosure. Refer to FIG. 1, a manufacturing method of a semiconductor device includes the following steps. First in step S1, coating a photoresist on a top surface of a substrate, in which the substrate is a hexagonal crystal structure and has a top surface perpendicular to a c-axis. Thereafter, in step S2, developing the photoresist such that an included angle is between a top surface of the photoresist and the substrate, in which the included angle is in a range from 30 degree to 60 degree. Thereafter, in step S3, etching the substrate with the photoresist such that a lattice plane of the substrate parallel to the c-axis is exposed. Following by step S4, growing an epitaxial layer on the substrate such that the epitaxial layer is grown along the lattice plane parallel to the c-axis. Finally in step S5, forming a transistor structure in the epitaxial layer, on the epitaxial layer and on a surface facing away from the epitaxial layer.

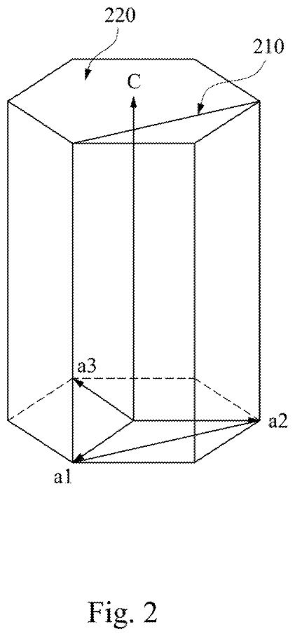

FIG. 2 is a perspective view of a unit cell of a hexagonal crystal structure. Refer to FIG. 2, when defining a lattice plane in a unit cell of a hexagonal crystal structure, different from the Miller indices used in a cubic crystal structure, Miller-Bravias indices are used to define the lattice planes. The reason of it is that the packing on the direction perpendicular to the c-axis cannot be properly defined by using only two indices. In Miller-Bravias indices, the four numbers in the brackets (such as the (11-20) lattice plane in the present disclosure) represents the reciprocal of the incident point of the lattice plane and the four axes a1, a2, a3 and c. If a particular lattice plane is parallel to an axis, the incident point can be interpreted as the infinity, which is zero after taking the reciprocal. Therefore, it can be understand that since the last index of the (11-20) lattice plane and the (1-100) lattice plane are both zero, the incident point of these lattice planes and the c-axis are both at the infinity, which means that the lattice planes are parallel to the c-axis. In FIG. 2, the plane 210 is the (11-20) lattice plane in the present disclosure.

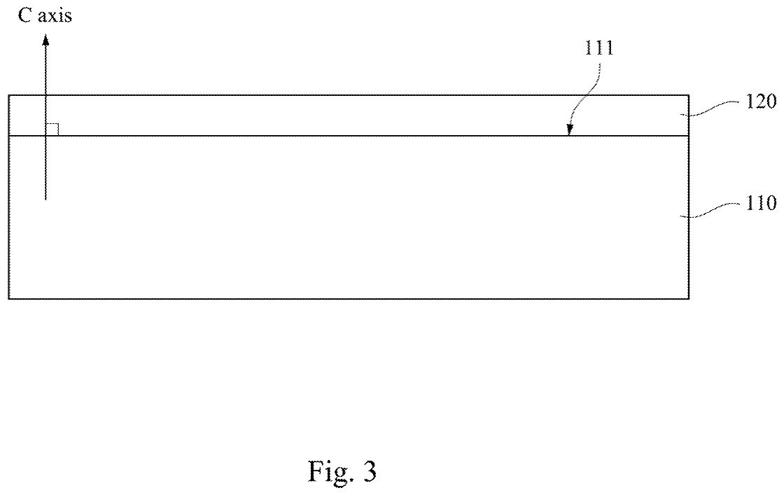

FIG. 3 to FIG. 7 are cross-sectional views of intermediate steps of the manufacturing method of the semiconductor device according to one embodiment of the present disclosure. Refer to FIG. 3, the manufacturing method of the semiconductor device includes coating a photoresist 120 on a top surface 111 of a substrate 110, in which the substrate 110 is a hexagonal crystal structure and has a c-axis. The top surface 111 is perpendicular to the c-axis and is correspond to a (0001) direction. The material of the substrate includes at least one of a diamond, a monocrystalline gallium oxide (Ga₂O₃), a polycrystalline gallium oxide, a monocrystalline silicon carbide (SiC), a polycrystalline silicon carbide, a monocrystalline gallium nitride (GaN) and a polycrystalline gallium nitride. For a substrate 110 that is made in a general fabrication, the surface for manufacturing devices is the “silicon side”, the Miller-Bravais indices of which is (0001), which is the surface 220 of FIG. 2. However, since this surface is perpendicular to the c-axis, in the steps thereafter, a transistor structure that is parallel to the c-axis can be manufactured.

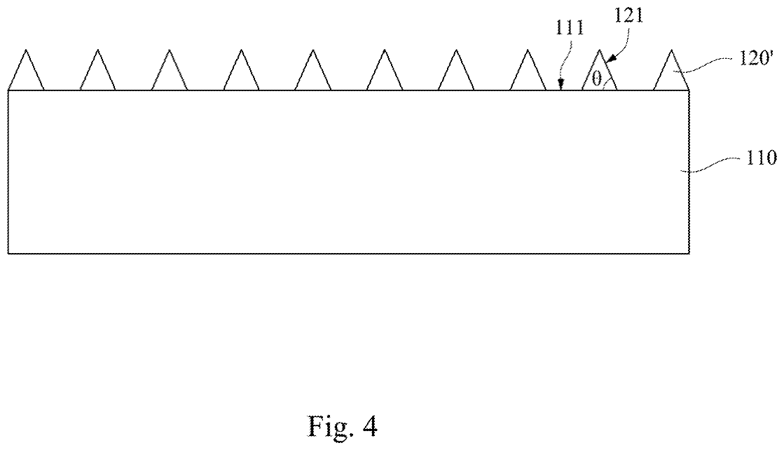

Refer to FIG. 4, after coating the photoresist 120 on the top surface 111, develop the photoresist 120, such that an included angle θ is between a top surface 121 of the developed photoresist 120′ and the substrate 100, in which the included angle θ is in a range from 30 degree to 60 degree. The included angle θ will affect whether a desired lattice plane can be etched in the etching step thereafter. In the present embodiment, the desired lattice plane is the lattice plane corresponds to the (11-20) direction or the (1-100) direction. Since the photoresist 120′ has an included angle θ after the development, the etching process is etched along the included angle of the photoresist 120′.

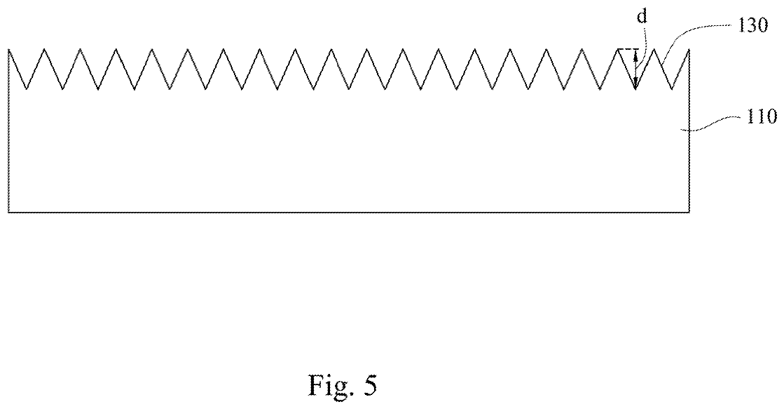

Refer to FIG. 5, etching the substrate 110 with the developed photoresist 120′ such that a lattice plane 130 of the substrate 110 is exposed, in which the lattice plane 130 is parallel to the c-axis and is correspond to the (11-20) direction or the (1-100) direction. The etching depth d is in a range from 500 angstrom to 1000 angstrom, and the etching is performed by dry etching. The gas used for dry etching can be sulfur hexafluoride (SF₆) or oxygen (O₂), or other gas the like to be the plasma gas for dry etching.

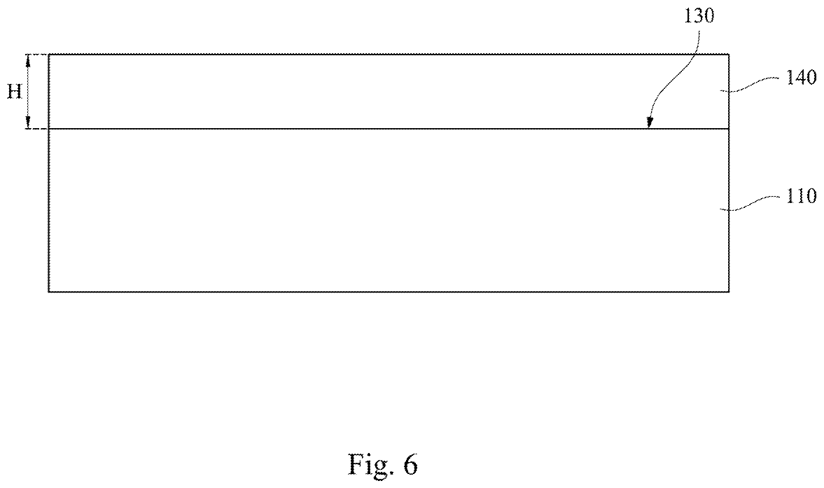

Refer to FIG. 5 and FIG. 6, after etching the substrate 110 and exposing the lattice plane 130 parallel to the c-axis and correspond to the (11-20) direction or the (1-100) direction, growing an epitaxial layer 140 on the lattice plane 130 and the epitaxial layer 140 directly contact the lattice plane 130. The material of the epitaxial layer 140 includes at least one of a diamond, a gallium oxide, a silicon carbide and a gallium nitride. The thickness H of the epitaxial layer 140 is in a range from 10 to 20 micrometers. Growing the epitaxial layer 140 on the substrate 110 is performed by metal-organic chemical vapor deposition (MOCVD), high temperature chemical vapor deposition (HTCVD), atomic layer deposition (ALD), molecular beam epitaxy (MBE) or other methods the like.

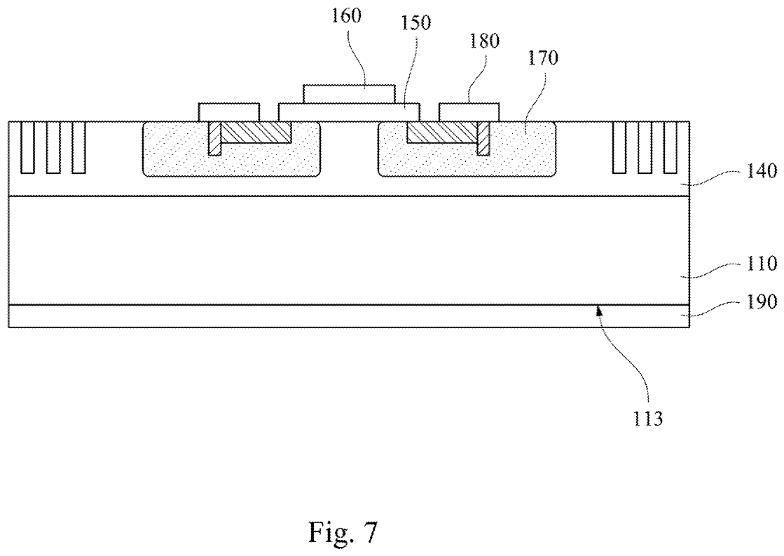

Refer to FIG. 7, after the growth of the epitaxial layer 140, form a transistor structure in the epitaxial layer 140 and on the epitaxial layer 140. The transistor structure includes a gate dielectric layer 150, a gate electrode 160, a well region 170 and a source area 180. The gate dielectric layer 150 is located on the epitaxial layer 140. The gate electrode 160 is located on the gate dielectric layer 150. The well region 170 is located in the epitaxial layer 140, in which the well region 170 is located under the gate dielectric layer 150. The source area 180 is located in the well region 170. The transistor structure at this step is not completely manufactured. The steps thereafter will further form another portion of the transistor structure on the other surface of the substrate 110.

After forming the transistor structure in the epitaxial layer 140 and on the epitaxial layer 140, forming a metal layer 190 on a surface 113 corresponds to the (000-1) direction. The metal layer 190 is a drain area in the transistor structure. Forming the transistor structure in the epitaxial layer 140, on the epitaxial layer 140 and on the surface 113 includes performing at least one of an oxidation, a photolithography, an etching and an ion implantation to form a portion of the transistor structure. For example, photolithography and etching can be used to pattern the gate dielectric layer 150 and the gate electrode 160, the ion implantation can be used to form the well region 170 and the source area 180, but not limited to these methods.

In summary, since a lattice plane 130 that is parallel to the c-axis and corresponds to the (11-20) direction or the (1-100) direction is formed using a photoresist 120′ with an included angle θ through the method of dry etching along the included angle θ of the photoresist 120′ before forming the transistor structure, when the epitaxial layer 140 grows thereafter, the epitaxial layer 140 can grow along the lattice plane 130 parallel to the c-axis. In the fabrication of the formation of the transistor structure thereafter, a transistor structure of which electron channel is parallel to the c-axis can be manufactured, such that the charge mobility in the charge channel can increase since the channel is parallel to the c-axis, the on-state resistance can be decreased, and thus the power consumption of the device can be decrease, such that the performance of the power device is better.

What is claimed is:

1. A semiconductor device, comprising:
a substrate having a hexagonal crystal structure and a top surface perpendicular to a c-axis, the top surface of the substrate comprises a lattice plane that is parallel to the c-axis, wherein the lattice plane is etched by using a developed photoresist, and an included angle between the top surface of the developed photoresist and the substrate is in a range from 30 degree to 60 degree;
an epitaxial layer located on the lattice plane; and
a transistor structure located in the epitaxial layer, on the epitaxial layer and on a surface facing away from the epitaxial layer.

2. The semiconductor device of claim 1, wherein a thickness of the epitaxial layer is in a range from 10 to 20 micrometers.

3. The semiconductor device of claim 1, wherein a material of the substrate comprises at least one of a diamond, a monocrystalline gallium oxide, a polycrystalline gallium oxide, a monocrystalline silicon carbide, a polycrystalline silicon carbide, a monocrystalline gallium nitride and a polycrystalline gallium nitride.

4. The semiconductor device of claim 1, wherein the epitaxial layer directly contacts the lattice plane.

5. The semiconductor device of claim 1, wherein a material of the epitaxial layer comprises at least one of a diamond, a gallium oxide, a silicon carbide and a gallium nitride.

6. The semiconductor device of claim 1, wherein a portion of the transistor structure is formed along the lattice plane, and the lattice plane corresponds to a (11-20) direction or a (1-100) direction.

7. The semiconductor device of claim 1, wherein the surface facing away from the epitaxial layer of the substrate is perpendicular to the c-axis and corresponds to a (000-1) direction.

8. The semiconductor device of claim 1, wherein the transistor structure further comprising:
a gate dielectric layer located on the epitaxial layer;
a gate electrode located on the gate dielectric layer;
a well region located in the epitaxial layer, wherein the well region is adjacent to the gate dielectric layer; and
a source area located in the well region.

9. A semiconductor device, comprising:
a substrate having a hexagonal crystal structure and a top surface perpendicular to a c-axis, the top surface of the substrate comprises a lattice plane that is parallel to the c-axis, wherein the lattice plane is etched by using a developed photoresist, and an included angle between the top surface of the developed photoresist and the substrate is in a range from 30 degree to 60 degree;
an epitaxial layer located on the lattice plane and directly contacts the lattice plane; and
a transistor structure located in the epitaxial layer and on the epitaxial layer.

10. The semiconductor device of claim 9, wherein a portion of the transistor structure is formed along the lattice plane, and the lattice plane corresponds to a (11-20) direction or a (1-100) direction.

11. The semiconductor device of claim 9, wherein the transistor structure further comprising:
a gate dielectric layer located on the epitaxial layer;
a gate electrode located on the gate dielectric layer;
a well region located in the epitaxial layer, wherein the well region is adjacent to the gate dielectric layer; and
a source area located in the well region.

12. A manufacturing method of a semiconductor device, comprising:
coating a photoresist on a top surface of a substrate, wherein the substrate is a hexagonal crystal structure and has a top surface perpendicular to a c-axis;
developing the photoresist such that an included angle is between a top surface of the photoresist and the substrate, wherein the included angle is in a range from 30 degree to 60 degree;
etching the substrate with the photoresist such that a lattice plane of the substrate parallel to the c-axis is exposed;
growing an epitaxial layer on the substrate such that the epitaxial layer is grown along the lattice plane parallel to the c-axis; and
forming a transistor structure in the epitaxial layer, on the epitaxial layer and on a surface facing away from the epitaxial layer.

13. The manufacturing method of the semiconductor device of claim 12, wherein coating the photoresist on the top surface of the substrate comprises coating the photoresist on a lattice plane perpendicular to the c-axis and corresponds to a (0001) direction.

14. The manufacturing method of the semiconductor device of claim 12, wherein forming the transistor structure in the epitaxial layer, on the epitaxial layer and on the surface facing away from the epitaxial layer comprising:
performing at least one of an oxidation, a photolithography, an etching and an ion implantation to form a portion of the transistor structure.

15. The manufacturing method of the semiconductor device of claim 12, wherein forming the transistor structure in the epitaxial layer, on the epitaxial layer and on the surface facing away from the epitaxial layer comprising:
forming a metal layer on the surface of the substrate.

16. The manufacturing method of the semiconductor device of claim 15, wherein forming the transistor structure in the epitaxial layer, on the epitaxial layer and on the surface facing away from the epitaxial layer comprising:
grinding the surface before forming the metal layer on the surface of the substrate.

17. The manufacturing method of the semiconductor device of claim 12, wherein an etching depth of etching the substrate with the photoresist is in a range from 500 angstrom to 1000 angstrom.

18. The manufacturing method of the semiconductor device of claim 12, wherein etching the substrate with the photoresist is performed by dry etching.

19. The manufacturing method of the semiconductor device of claim 12, wherein growing the epitaxial layer on the substrate such that a thickness of the epitaxial layer is in a range from 10 micrometers to 20 micrometers.

20. The manufacturing method of the semiconductor device of claim 12, wherein growing the epitaxial layer on the substrate is performed by a metal-organic chemical vapor deposition (MOCVD), a high temperature chemical vapor deposition (HTCVD), an atomic layer deposition (ALD) or a molecular beam epitaxy (MBE).
